(19) United States
(12) Patent Application Publication
(10) Pub. No.: US 2017/0005253 A1
(43) Pub. Date: Jan. 5, 2017

(54) Radiance Capture Techonolgy

(71) Applicant: Harold Winslow, Butner, NC (US)

(72) Inventor: Harold Winslow, Butner, NC (US)

(21) Appl. No.: 14/634,763

(22) Filed: Mar. 30, 2015

(51) Int. Cl. H01L 35/32

(52) U.S. Cl. CPC H01L 35/325

(57) ABSTRACT

I. Radiance Capture Technology [RCT] uses established science, in thermal and wave generated energy, which is “captured” in and through a central “Capture Core” of a totally new design and aided by 21st century digial processing platforms. Utilizing a non-weaponable, modern level, Isotope [Thorium-Fluride], which generates heat and wave radiations, that are totally absorbed between Thermocouples [TCs] and “reverse Faraday-style” gridsby and through conductible and non-conductible materials and is, thereby, converted to usable electricity by compounding that energy transmitted through TCs in a repetition of “cycles in series”; Grid Wave capture and channeled by the appropriate size diode and capacitor arrays for a scalable source of usable electrical generation.

A unique modification and assemblage of various established sciences into a new Solid-State, Non-Moving part, Electrical Generation Process using Meta-Material insulated probes, of selected metals, capturing the heat energy from “Gradient Across Junctions” (Beck Effect) combined with wave energy capture by a co-connected grid network (“reverse” Faraday Box) which is capable of simultaneously processing both radiant energies from a non-weaponable Isotope into usable electricity. “Thermoductor”, “DioPacitor”, “TransVerter”, “Capture Core”, and “Series Cycle” designations are for RCT sub-assemblies/processing.

### DRAWINGS

FIG. 1 is a schematic showing the RCT subassemblies and Capture Core embodying the process and preferred embodiment of the present invention.

FIG. 2 is a vertical cross section of the present invention, showing the Capture Core structure 7 including shell supports 2, thermocouple layout 7 and isotope pedestal 3.

FIG. 3 is a side view and front view of the thermocouple structure, the side view showing the thermocouple structure with terminals used in series cycle and a front view of the thermocouples interlocking with the pentagon shape to attain spherical inner-chamber shape.

FIG. 4 is a vertical cross section of the Capture Core with Farrady Grid Layers shown between shell layers and the central isotope pedistal. Outer layers indicate metamaterial shielding.

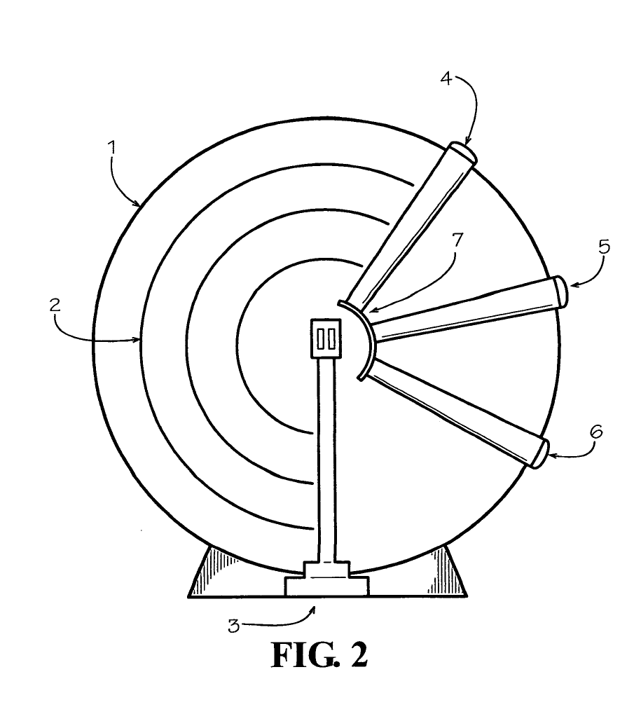

FIGS. 2-4 show the generated “flow” and direction, by shaded “conduit” symbology.

### DESCRIPTION

The RCT Capture Core 7 fuses the above newly created and developing combinations to establish the process of the present invention.

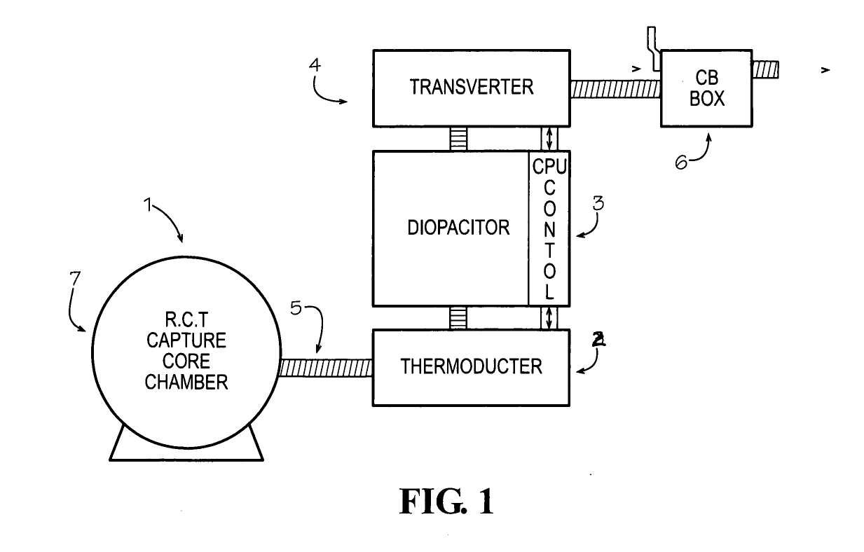

The Thermal Energy and Wave energy inducted are collected from the Capture Core 7 and supplied to the wiring inside the Conduit 5. This surrounding wiring directs the output of the DioPacitor array, as shown in FIG. 1.

The Diode-Capacitor combination structures the “Series Cycle” effect of increasing energy output by Thermocouples “in-series” wiring and the DioPacitor array “Cycles” the “Series” repetitively, until the desired output is reached for the Capacitors' selected discharge level.

The Transformer-Inverter array 4 receives and transforms the generated electricity by boosting and controlling output cycles per second for end use as per existing transformers and inverters have done separately with less efficiency. This New Construct, much like the DioPacitor array, is arranged and specifically formulated for the exact output based on Capture Core capacity and size. In this way, the RCT concept is further a unique construct/process.

The present invention can be used domestically in home as demonstrated by the inclusion of a whole house circuit breaker box 6 (inside the System's Cabinet), where the final connection for RCT output is focused on end use in home.

As shown in FIG. 2, RCT Capture Core, (front view cut away) shows the outer layer of proposed metal or metal alloy 7 Outer Shell for the capture element of the RCT Process/Device.

Indicated layer 1 of FIG. 2 shows [“reverse Faraday Box”] Absorption Grid Network surrounding the Thermocouple probes. Grid layers capture radiant wave energy, while probes gather radiant heat energy. Polycarbonate resin spheres located behind the grids, proves platform structure for grid strength and stability. Meta-Material “honeycomb” 7 surrounds the probes, insulating them from one another in energy gathering. Additional Meta-Material layering on the backs of the polycarbonate resin spheres creates a shield preventing energy “leakage” past the collection grids

The Isotope “pedestal” 3 is charged with a Thorium-Flouride compound. Thorium is a non-weaponable, moderate yield Isotope with a 15 [] year half-life. Flouride combines with the Thorium to control temperature of the Thorium sample.

Platinum-Rhodium or other metal bonding provides the basis for high transmission thermo-couple (“TC”) activity. Wired in a progressive number of Series connections 4, 5, 6, allows energy to expand upon itself in “cycles” (The “series cycle” designation of method) as controlled by circuitry and digital control boards (See CPU Section in FIG. 1). The initial shape/design is generally “pentagonal” for the purpose of creating an “interlocking pattern” which constitutes a structure similar to a hollow geodesic dome.” This preferred design will insure total encapsulation of the isotope and transient heat and wave energy to be gathered by the probes and grids as noted above.

Separate numbers of TC probes, and their “Series Cycle” circuits, create the repetition of cycles as co-located receptors build the energy output.

Other embodiments of the invention may have a number of probes and grids varying from those shown in FIGS. 2-4.

Internal Geodesic “wall” 2 of Capture Core has Meta-Material “Insulators/Bushings” to hold and position probes in di-electric separation from one another and provide a non-penetrative platform “honeycomb” to secure the probes and grids in relation to the isotope.

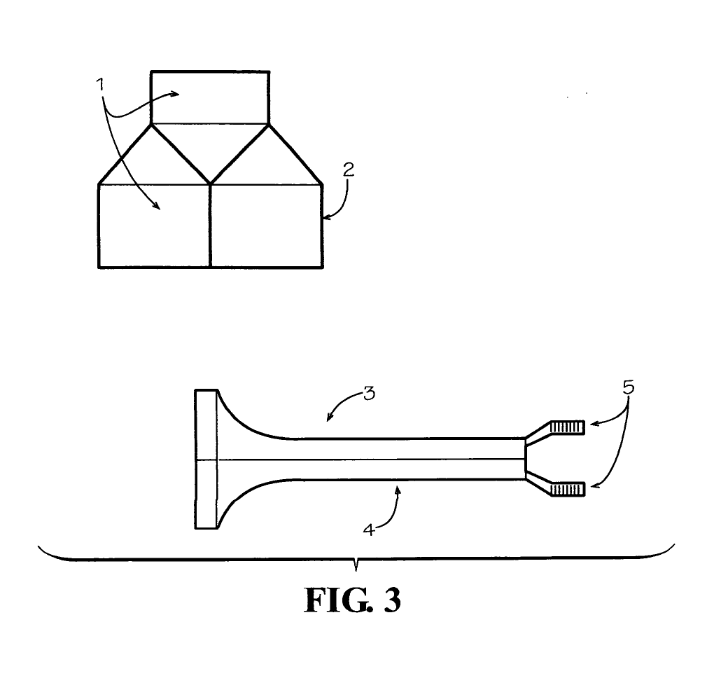

As shown in FIG. 3, TC Probes 1 of generally concave, pentagonal shape, allow a “geodesic” construct to form an interlocking hollow sphere of the Capture Core, completely enclosing the Isotope from every possible angle.

Meta-Material Insulators (Bushings) 2 are derived from a honeycomb-like structure within the geodesic structure and sized to the required scale for capture, output and scalability factors. Platinum portion of the TC Probes 3 indicate threaded terminals for energy input. Rhodium portion of the TC Probes 4 indicate threaded terminals for energy output.

Electrical terminals 5 for connecting the input/output wiring in series creates the power build-up/increases experienced in the RCT function. The thermocouples bring the charges to the circuitry for generation gathering and collection by series redundancy.

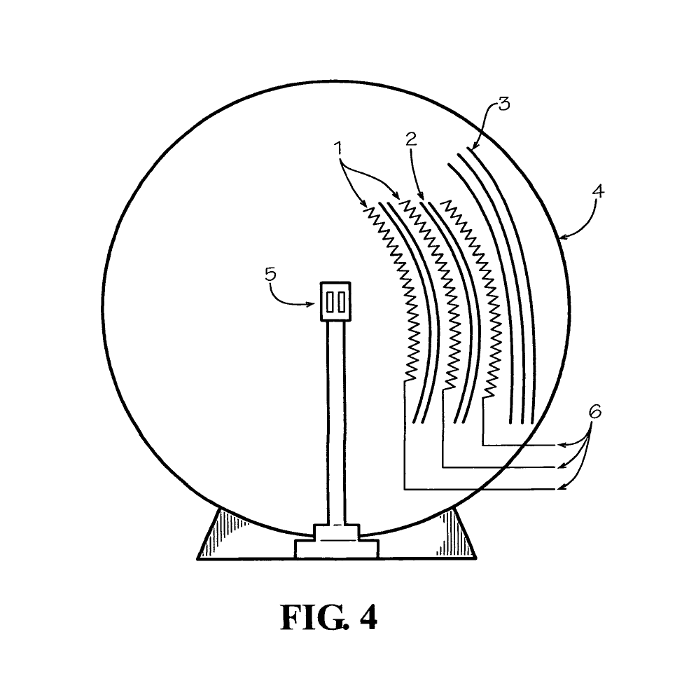

As shown in FIG. 4, the Faraday-style Grids 7 gather wave energy from within, rather than blocking from without. This is done with overlapping layers of grids to ensure total collection is served by any radiant direction experienced inside the Capture Core.

Polycarbonate resin spheres 2 contain the Grids to allow stability and support to their structure and form function. These are placed in concentrically-larger layers as the energy needs and scaling are determined and constructed.

Meta-Material spheres 3 (“Shield Shells”) are the outermost internal layer before the Capture Core outer shell of chamber surface is enclosed. Meta-Material construct will evolve with the Size and Thickness, depending on the degree of shielding required by each use and Capture Core sizes.

The outer shell of the Capture Core Chamber 4 is proposed as stainless steel. Other materials may be efficacious, depending on weight, use, size of form factor and power needs.

Isotope “Pedestal” 5 allows the Thorium-Flouride Isotope to be inserted at the center of the TC boundary inner layer. A ceramic material proposed to contain heat and provide long-term protection against the deterioration of containment vessel.

Circuitry is connected to Grids 6 and channeled through conduit to circuitry arrays for processing. TC Probes have separate circuits taking advantage of the Series power increases, and for supplying that portion of Energy capture process.

By the process described above, the present invention accomplishes solid state non-moving part electrical generation by computer-controlled thermo and inductive energy capture.

1. Inventor distinctly and particularly make claim to: Radiance Capture Technology [RCT] as creating this new method/process for directly capturing, absorbing, processing, converting and generating usable electricity from radiant heat and energy wave sources utilizing the RCT “Capture Core Chamber”, and the newest materials and digital circuitry interactive in a heretofore uncombined manner and design. RCT wherein the improvement comprises the mixing of: a solid state collection and processing of energy with no moving parts [e.g. a gas engine-powered generator] in a unique assemblage of established and emerging sciences. For example, Thermocouples [TCs] of the latest materials for maximum conduction supersedes original discoveries; these, combined with layers of metallic “capture grids”, over-layed inside a spherical construct of polymers and other new Meta-materials, are used to channel the energy gathered directly to computer chip operated digital circuitry control devices and subassemblies capable of generating usable electric output. Scalability factors are an inherent key form and benefit of RCT's capture capabilities and load generation which are among the benefits of this new innovative technique and process construct. With the discovery of total, energy absorption of certain Meta-materials, the final problem was solved to effect the construction of the Capture Core of RCT and bring this long sought design to creation and fruition. The initial design of RCT's “Capture Core” is a geodesic sphere whose inner surface is entirely enclosed in pentagon shaped thermocouple probe receptors. These arrays are shaped much like the pattern found in a soccer ball. Depending on the scalability mentioned earlier the output features desired. The Thorium-Florida isotope is ceramic pedestal for gathering the heat generated from every internal direction. RCT takes full advantage this enclosure and channels it directly to the processing and collecting circuits. RCT gathers both HEAT and WAVE Energies to make TOTAL ABSORPTION a reality of use and proof of conceptual performance.
